(19) United States
(12) Patent Application Publication
(10) Pub. No.: US 2024/0196754 A1
(43) Pub. Date: Jun. 13, 2024

(54) LATERAL HETEROSTRUCTURE ISOLATED COUPLED QUANTUM DOTS

(71) Applicant: International Business Machines Corporation, Armonk, NY (US)

(72) Inventors: Bogdan Cezar Zota, Rueschlikon (CH); Kirsten Emilie Moselund, Rueschlikon (CH); Peter Mueller, Zurich (CH)

(21) Appl. No.: 18/063,950

(22) Filed: Dec. 9, 2022

(51) Int. Cl. H10N 50/01; H10N 50/80; H10N 50/85

(52) U.S. Cl. CPC H01L 43/12; H01L 43/02; H01L 43/10; B82Y 10/00

(57) ABSTRACT

A method for forming a semiconductor structure comprising isolated coupled quantum dots defining a physical spin qubit is disclosed. The method comprises structuring the doped silicon layer using an SIO substrate with a source area structure, a linear structure extending from the source area, gate structures extending vertically to a main extension direction of the linear structure, covering the structures with an oxide, removing the oxide at a lateral end of the linear structure, laterally etching back the linear structure between the blanket oxide and the SOI isolator, epitaxial filling the hollow template with a first semiconductor material different from the silicon, continuing the epitaxial and laterally filling the hollow template with an alternating sequence of lateral thin layers of a second and a third semiconductor material, and continuing the epitaxial filling the hollow template with the first semiconductor material until an end of the hollow template is reached.

### BACKGROUND

The invention relates generally to a method for forming a semiconductor structure, and more specifically, to a method for forming a semiconductor structure comprising isolated coupled quantum dots defining a physical spin qubit. The invention relates further to a structured semiconductor device comprising isolated coupled quantum dots defining a physical spin qubit.

Quantum computing remains one of the hottest topics in physical science, the industry and in research. Classical digital computers and/or processors are slowly reaching their physical limitations, so research is looking for new ways to address mathematical and other problems that cannot be solved by classic von-Neumann machines due to the physical limitations in terms of structure size, power consumption and ultimately speed of processing.

Quantum computing is thus one of the promising areas to reach quantum supremacy, i.e., a real advantage in addressing very complex computation or tasks in reasonable times. As is well known, conventional computers encode process information in bits, i.e., “1”s and “0” s. Quantum computers, on the other hand, are based on so-called qubits which operate according to two key principles of quantum physics: superposition and entanglement. Superposition describes a situation that each qubit can represent both, a 1 and a 0 inference between possible outcomes for an event. Entanglement means that qubits in superposition can be correlated with each other in a non-classical way, i.e., the state of one qubit, whether it is a 1 or a 0 or both, can depend on the state of another, and that there is more information contained in qubits when they are entangled compared to single ones.

In general, a quantum state is the mathematical description of the state of an atomic or subatomic-size system. This is described as a vector in a vector space over complex numbers, popularly known as the Hilbert space. A quantum state can thereby describe any properties of the quantum particle or system of quantum particles, e.g., that position, momentum, quintessential phenomenon like quantum spins, and so on. Some of these properties are continuous variables and are therefore represented by vectors in the infinite-dimensional Hilbert space; position and momentum as variables are examples of this. However, other properties such as the spin of a particle can only assume definitive many quantized values and are therefore finished-dimensional. For example, the spin-part of the state of a quantum system with “n” electrons can be a state inside a 2n dimensional Hilbert space. Hence, the Hilbert space for “n” qubit quantum computer scales as 2n. Intuitively, each qubit in a quantum computer is not averse to a bit in the classical digital computer system. However, several qubits to gather in a system can explore a full “n”-dimensional Hilbert space instead of requiring 2nd classical bits to do the same. Hence, superposition and entanglement are two unique quantum properties that qubits possess over their classical counterparts.

### SUMMARY

According to one aspect of the present invention, a method for forming a semiconductor structure comprising isolated coupled quantum dots defining a physical spin qubit may be provided. The system may comprise providing silicon-on-isolator substrate comprising a doped silicon layer atop an isolator and structuring the doped silicon layer to form the following structure: a source area structure, a linear structure extending from the source area where the linear structure has a first width which is smaller than a main area of the source area, and gate structures extending vertically to a main extension direction of the linear structure where the gate structures are isolated from the linear structure, and where the gate structures define at least a first and a second gate area.

The method further may comprise covering the structures with a blanket oxide layer, removing the blanket oxide at a lateral end of the linear structure opposite to the source area such that an opening is created in the blanket oxide, and laterally etching back the linear structure between the blanket oxide and the isolator until an area near the source area is reached, thereby forming a hollow template between the isolator and the blanket oxide layer.

Additionally, the method may comprise epitaxial and laterally filling the hollow template with a first semiconductor material different to the silicon such that the hollow template is filled up to a first length extending from the source area, continuing the epitaxial and laterally filling the hollow template with an alternating sequence of lateral thin layers of a second semiconductor material and a third semiconductor material, such that at least two thin layers of the second semiconductor material and three thin layers of the third semiconductor material are deposited, such that the lateral thin layers of the third material are positioned in a planes defined by the first and the second gate area, and continuing the epitaxy and lateral filling of the hollow template with the first semiconductor material until an end of the hollow template is reached.

According to another aspect of the present invention, a structured semiconductor device comprising isolated coupled quantum dots defining a physical spin qubit may be provided. The device may comprise a silicon structure on an isolator building a source area and a linear structure on an isolator, where the linear structure extends from the source area, where the linear structure has a width which is smaller than a main area of the source area, where the linear structure may comprise a first area of a first semiconductor material, and a separated second area of the first semiconductor material, an array of regularly spaced at least two thin, free-standing segments having a same lateral cross section as the first area and the second area of the first semiconductor material, where the segments of the array are located on the isolator, where the segment are isolated from each other, by a dielectric material, and gate structures extending vertically to a main extension direction of the linear structure, where the gate structures are isolated from the linear structure, and wherein the gate structures define at least a first and a second gate area, such that the array of the at least two thin, free-standing segments define at least two quantum dots as a basis for at least one physical spin qubit.

### BRIEF DESCRIPTION OF THE DRAWINGS

It should be noted that embodiments of the invention are described with reference to different subject-matters. In particular, some embodiments are described with reference to method type claims, whereas other embodiments are described with reference to apparatus type claims. However, a person skilled in the art will gather from the above and the following description that, unless otherwise notified, in addition to any combination of features belonging to one type of subject—matter, also any combination between features relating to different subject—matters, in particular, between features of the method type claims, and features of the apparatus type claims, is considered as to be disclosed within this document.

The aspects defined above and further aspects of the present invention are apparent from the examples of embodiments to be described hereinafter and are explained with reference to the examples of embodiments, to which the invention is not limited.

Preferred embodiments of the invention will be described, by way of example only, and with reference to the following drawings:

FIG. 1 shows a block diagram of an embodiment of the inventive method for forming a semiconductor structure comprising isolated coupled quantum dots defining a physical spin qubit.

FIG. 2 shows options for additional method steps, in accordance with an embodiment of the present invention.

FIG. 3 shows a layered structure of a wafer, an oxide and a silicon-on isolator substrate, in accordance with an embodiment of the present invention.

FIG. 4 shows the structures which have been isolated from the silicon layer of the SOI layer, in accordance with an embodiment of the present invention.

FIG. 5 shows the blanket oxide over the source area and the linear structure, in accordance with an embodiment of the present invention.

FIG. 6 shows the status of the blanket oxide 502 after the linear structure has been etched away under the blanket oxide, in accordance with an embodiment of the present invention.

FIG. 7 shows the situation after an epitaxial regrowth of a heterostructure in the hollow template, in accordance with an embodiment of the present invention.

FIG. 8 shows the situation after the blanket oxide has been removed and the heterostructure becomes completely visible, in accordance with an embodiment of the present invention.

FIG. 9 shows the result of etching away the material of the second semiconductor material, in accordance with an embodiment of the present invention.

FIG. 10 shows how the portions of the heterostructure are covered with metal contacts, in accordance with an embodiment of the present invention.

FIGS. 11, 12, 13 show the method steps in a shortened sequence, in accordance with an embodiment of the present invention.

FIG. 12 shows an intermediate fabrication result of additional process steps, in accordance with an embodiment of the present invention.

FIG. 13 shows the structures according to FIG. 12 in which additional metal contacts have also been added, in accordance with an embodiment of the present invention.

FIG. 14 shows a split view of the substrate layers and the oxide layer above each other structured components of the heterostructure, in accordance with an embodiment of the present invention.

FIG. 15 shows the Si layer and the layer directly atop each other, in accordance with an embodiment of the present invention.

FIGS. 16 to 23 show more useful fabrication steps in series when using the buried gates, in accordance with an embodiment of the present invention.

### DETAILED DESCRIPTION

In the context of this description, the following technical conventions, terms and/or expressions may be used:

The term ‘quantum dot’ may denote a nanoscopic material structure made of semiconductor material—e.g., SiGe or III-V semiconductors—comprising charge carriers that are limited in its degree agree to move freely in all three spatial directions. As a consequence of the small structure, the energy of the charge carriers cannot be changed continuously but only in discrete steps. Hence, quantum dots behave in a comparable way to atoms; however, its form, size and number of electrons or charge carriers can be influenced. The energy levels for traditional quantum dots used for quantum devices may be defined by an electrostatic confinement. In the concept proposed here, this is not required. Instead, the confinement may be reached only via the geometry of the quantum dots.

The term ‘isolated coupled quantum dots’ may denote geometrically defined fin-type segment (or pillars) of a semiconductor material between a source area and a drain area. Each fin or quantum dot may be electrically isolated against each other and against other structural components of a heterostructure. This way a physical spin qubit device may be defined.

The term ‘physical spin qubit’ may denote here a physical device comprising coupled quantum dots defined by geometry. For this type of quantum dots no external confinement may be required in order to result in discrete energy levels. Hence, all implemented gate structures may be used as read-out gates. This may allow a high number of coupled qubit devices.

The term ‘linear structure’ may also be denoted as a one-dimensional structure. In this case, a thin layer of a semiconductor on an oxide. Thereby, the longitudinal dimension of the linear structure is much, much larger than in the other two dimensions vertical to the linear extension.

The term ‘blanket oxide layer’ may denote an oxide, e.g., SiO₂ or another dielectric covering all Si structure elements that have been lithographically fabricated out of a SOI base material.

The term ‘hollow template’ may denote a sort of tunnel or horizontal cavity below and in-between the blanket oxide layer and the supporting oxide layer.

The term ‘alternating sequence of lateral thin layers’ may denote vertically oriented layers in respect to an SOI substrate. The layers may have a thickness of around 10 nm or significantly below. Their thickness is not defined by photolithography masks but by depositing parameter values. The growth rate may be controllable with high precision. This way, the layers of the third semiconductor material may be aligned with the gate structures which may have been built before.

Embodiments of the present invention realize that quantum gates remains a challenging area. Very low temperatures close to Absolute Zero are currently used and research is presently carried out on a large number of different realizations of quantum devices. Thereby, it is highly desirable to use existing fabrication techniques known in the field of classical chips, e.g., based on Silicon. In this field, metal-oxide-semiconductor field-effect transistors (MOSFET) are the typical workhorses for a wide range of scalable electronic platforms. In the field of qubit devices, spin qubits are one of the most promising alternative qubits due to the potentially high scalability and attractive properties. They have the potential to evolve as the natural choice for physical quantum devices.

One of the key scalability challenges is that when the physical qubit is defined by geometry or a heterostructure of semiconductor layers, to reduce the number of input lines to the physical qubit device than the necessary control gates must be placed in a process at where which it is difficult to align the required physical structures. This has an impact on scalability, minimum device features and finally fabrication yield. This can be seen in the example of a basic implementation of the qubit device using nanowire/fin-type structures. A realistic device will likely require at least three additional gates to set the confinement potential in order to achieve discrete energy levels, as well as additional read outlines. In particular, the comparably high number of confinement and read out gates for a single devise are counterproductive for a scalability to many thousand physical qubit devices.

Embodiments of the present invention provide for a method for forming a semiconductor structure comprises isolated coupled quantum dots defining a physical spin qubit may offer multiple advantages, technical effects, contributions and/or improvements:

The proposed embodiment for building a physical qubit device comprising coupled quantum dots may comprise good controllable alignment of gate structures and related quantum dots. Thereby, the gate structures may define a virtual plane in which the layers of the quantum dots should be deposited. The used epitaxy process TASE (template assisted selective epitaxy) may allow a good control of the deposited layer (i.e., vertical in respect to the substrate). This way, a good geometric alignment—in a range of up to 1 nm precision—between the gate structures and the quantum dots may be achieved.

The here proposed embodiment may also provide geometrically defined quantum dots as fin-like segments of areas of a linear structure, so that generally no gates are required to set the confinement potential for the quantum dots. Instead, the available gates may be used to apply other control signals and for read-out purposes. In traditional setups gates may be required in order to define the confinement of achieving quantized energy level within the quantum dots.

This may enable good scalability to a much larger number of coupled quantum dots without further limitations. It may also overcome the so far existing challenge to position the gates in a separate lithographic step in relation to the—potentially electrostatically defined—quantum dots. Both challenges may be overcome with the here proposed embodiment of the present invention. Hence, the requirement for at least three additional gates for a minimum of two coupled quantum dots of a physical qubit device is no longer existing because the quantum dots are defined geometrically using controlled epitaxy. Hence, a scalability of up to many thousands of quantum devices seems possible.

As a result, quantum dots can be densely packed in an array offering high opportunities for strongly interacting qubit devices. Furthermore, the typically 10 nm quantum dots with a 10 nm spacing (which is only limited by the used lithography system) may easily be controlled by traditional semiconductor fabrication techniques. Because of this, also quantum dot charge sensors can be integrated within the same lithography step and on the same substrate. Hence, the proposed embodiment represents a complete concept of simplifying an integration of traditional electronic components for control lines and read-out circuits for coupled quantum dots defining physical qubit devices.

In the following, additional embodiments of the present invention—applicable to the method as well as to the structured semiconductor device—will be described.

According to an advantageous embodiment of the method, the first semiconductor material may be different to the second semiconductor material, the second semiconductor material may be different to the third semiconductor material and wherein the first, the second and the third semiconductor material may be different from silicon. Hence, a heterostructure of different semiconductor materials may be built. Thereby, the first, the second and the third semiconductor material may be a combination of III-V semiconductors. Alternatively, also II-VI semiconductor heterostructures or GeSi may be used.

According to a preferred embodiment, the method may comprise removing the blanket oxide layer, and—in particular subsequently—selectively removing the thin layers of the second semiconductor material such that an array of quantum dots of the third semiconductor material may remain freestanding on the isolator and between the first semiconductor material. This way, fins of the third semiconductor material remain which may define the quantum dots in between the bulk first semiconductor material of the linear structure.

According to a useful embodiment of the method, the first semiconductor material may be InGaAs as an example of a III-V semiconductor material.

According to another useful embodiment of the method, the second semiconductor material may be InP. And according to a further useful embodiment of the method, the third semiconductor material is InAs. Hence, the heterostructure may be completed with a combination of III-V semiconductor materials. One of the advantages of III-V semiconductor material is that the carrier mobility is higher if compared to silicon. The combination of layers may be useful because of the respective etch selectivity. InP as the second semiconductor material is good removable between InGaAs—i.e., the first semiconductor material—and InAs—i.e., the third semiconductor material, i.e., the one of the quantum dots.

According to a preferred embodiment, the method may also comprise filling gaps between the first and the third semiconductor material with a dielectric material. This may be possible, because the second semiconductor material may have been removed by now. The dielectric material may also physically stabilize the thin layer fins—i.e., the quantum dots—of the third semiconductor material.

According to another preferred embodiment of the method, the gate structures may be fin-like structures that extend vertically away from the main extension direction of the linear structure on the oxide. This may represent a first alternative for a position of the gate structures.

According to another interesting embodiment of the method, the gate structures may be buried gates positioned in the oxide of the silicon-on-isolator substrate. This may represent a second alternative for gate structures. Ideally, they may be structured into the oxide of the SOI substrate before the other structures may be fabricated, namely, the linear structure, the hollow template, etc. This alternative embodiment may represent a more compact version. Furthermore, a second set of gate structures may be positioned at atop the dielectric covering the fins of the third semiconductor material.

According to an advanced embodiment, the method may also comprise depositing a metal source contact on an area of the first semiconductor material adjacent to the source area of the silicon layer, and depositing a metal drain contact on an area of the first semiconductor material which related to the lateral end of the hollow template before the blanket oxide was removed. For this, traditional covering and deposition methods may be used.

According to another enhanced embodiment, the method may also comprise depositing a first metallic gate contact over the isolator of the substrate—i.e., of the SOI substrate—where the first metallic gate contact may be in electrical contact with a first gate structure of the gate structures, and depositing a second metallic gate contact over the isolator of the substrate—i.e., of the SOI substrate—where the second metallic gate contact is in electrical contact with a second gate structure of the gate structures. Additionally, all now fabricated structures may be covered with a protective layer of SiN, an oxide (e.g. SiO₂) or another dielectric material.

In the following, a detailed description of the figures will be given. All instructions in the figures are schematic. Firstly, a block diagram of an embodiment of the present invention provides a method for forming a semiconductor structure comprising isolated coupled quantum dots defining a physical spin qubit is given. Afterwards, further embodiments, as well as embodiments of the structured semiconductor device comprising isolated coupled quantum dots defining a physical spin qubit will be described.

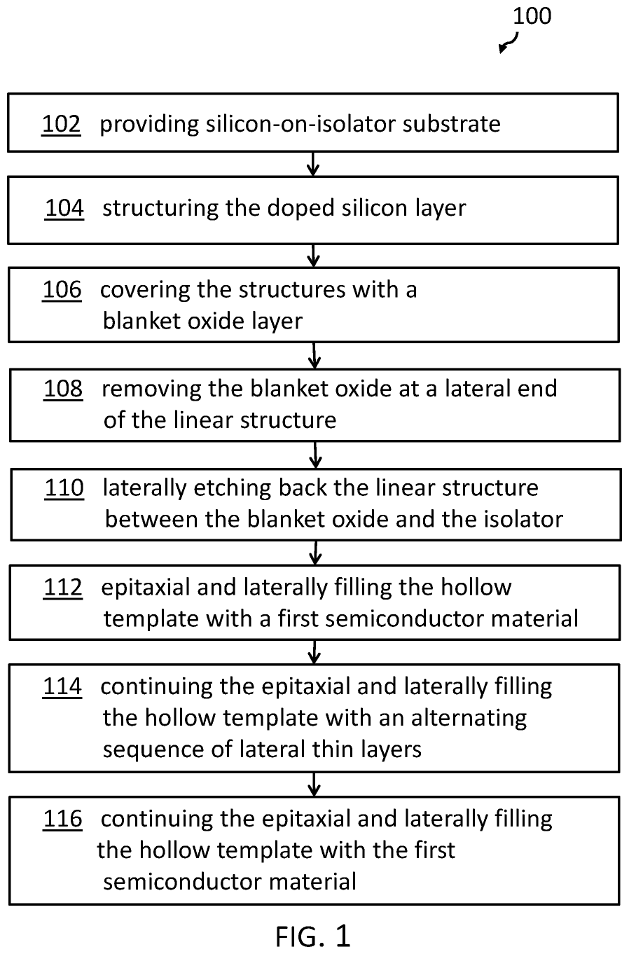

FIG. 1 shows a block diagram of a preferred embodiment of the method 100 for forming a semiconductor structure comprising isolated coupled quantum dots defining a physical spin qubit. The method comprises providing, 102, silicon-on-isolator substrate comprising a doped silicon layer atop an isolator, structuring, 104, the doped silicon layer—in particular by known mask/lithography and etching steps—to form the following structure: a source area structure, a linear—also denotable as one-dimensional—structure extending from the source area, where the linear structure has a first width which is smaller than a main area of the source area, and gate structures extending vertically to a main extension direction of the linear structure, wherein the gate structures are isolated from the linear structure, and where the gate structures define at least a first and a second gate area.

The method 100 also comprises covering, 106, the structures with a blanket oxide layer, removing, 108, the blanket oxide at a lateral end of the linear structure opposite to the source area such that an opening is created in the blanket oxide, and laterally etching back, 110, the linear structure between the blanket oxide and the isolator—i.e., from the SOI—until an area near the source area is reached, thereby forming a hollow template between the isolator and the blanket oxide layer.

Furthermore, the method 100 comprises epitaxial and lateral filling, 112, (i.e., re-growing) the hollow template with a first semiconductor material—e.g., InGaAs—which differs from the silicon so that the hollow template is filled up to a first length extending from the source area, continuing the epitaxial and lateral filling, 114, the hollow template with an alternating sequence of lateral thin layers of a second semiconductor material—e.g., InP—and a third semiconductor material—e.g., InAs—such that at least two thin layers of the second semiconductor material and three thin layers of the third semiconductor material are deposited, such that the lateral thin layers of the third material are positioned in planes defined by the first and the second gate area, and continuing, 116, the epitaxial and lateral filling the hollow template with the first semiconductor material until an end of the hollow template is reached. In other words, a template assisted selective epitaxy (TASE) process is used. The thickness of the second and the third semiconductor layer can be in a range of about 10 nm but may also go down to 5 nm or even 3 nm.

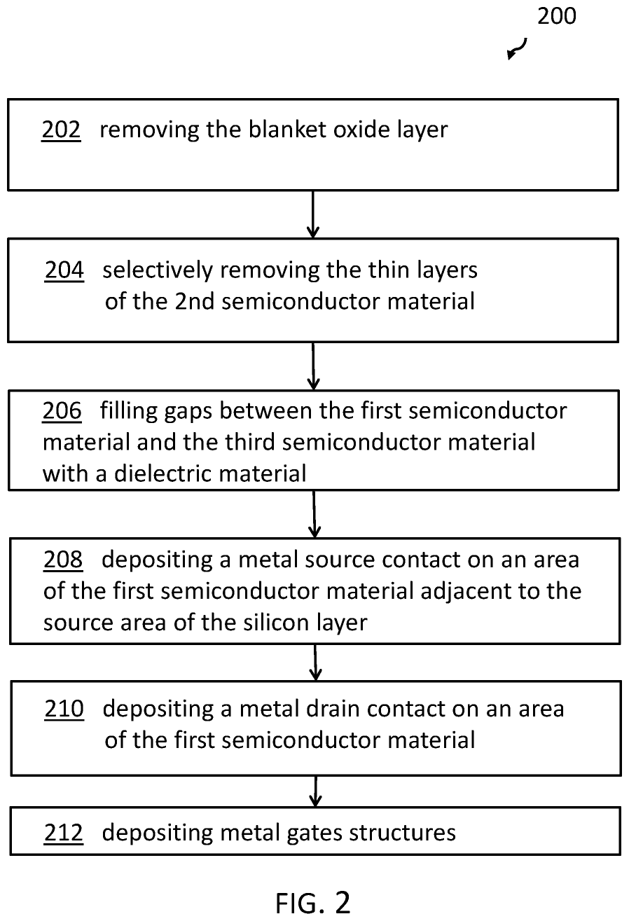

FIG. 2 shows additionally useful method steps in order to fabricate a functioning semiconductor quantum device comprising quantum dots. These additional method steps 200 do not have to be applied completely in the shown order. Other orders of application—or only a part of the shown method steps—may be useful. These additional method steps comprise (i) removing (202 the blanket oxide layer, (ii) selectively removing, 204, the thin layers of the second semiconductor material, such that the thin layers or fins of the third semiconductor material stand isolated on the oxide, (iii) filling, 206, gaps between the third semiconductor material and the third semiconductor material with a dielectric material which may also be deposited between the two fins of the third semiconductor material. Furthermore, the dielectric material may also cover the top of the named fins or segment.

Furthermore, the additional method steps 200 may also comprise (iv) depositing, 208, a metal source contact on an area of the first semiconductor material adjacent to the source area of the silicon layer adjacent to the source area of the silicon layer, and (v) depositing, 210, a metal drain contact on an area of the first semiconductor material which relates to the lateral end of the hollow template before the blanket oxide was removed, and (vi) depositing, 212, metal gate contacts, namely, a first metallic gate contact over the isolator of the substrate, where the first metallic gate contact is in electrical contact with a first gate structure of the gate structures, and depositing a second metallic gate contact over the isolator of the substrate, where the second metallic gate contact is in electrical contact with a second gate structure of the gate structures.

FIG. 3 shows a layered structure of a wafer 302, e.g., silicon, an oxide 304 and a silicon layer 306. This may also be denoted as silicon-on-isolator (SOI) substrate.

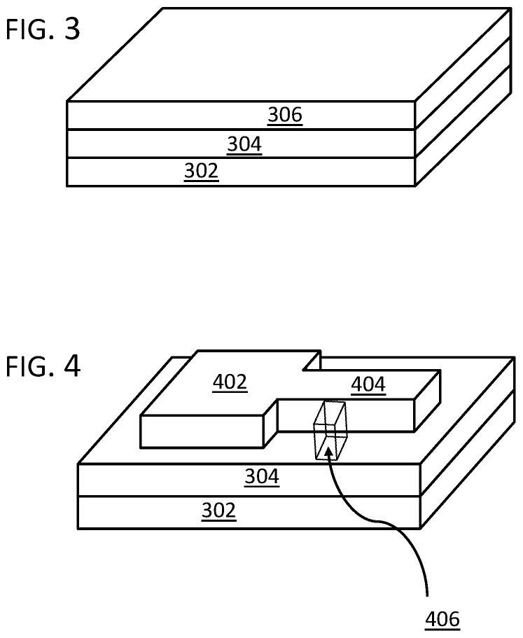

FIG. 4 shows the following structures which have been isolated from the silicon layer 306 (compare FIG. 3), namely, a source area 402, a linear or “one-dimensional” structure 404 and one of a potential plurality of gates extending vertically but isolated from the linear structure 404. At least a second gate (not shown) may be positioned beside the fin-like gate structure 406 or on the other side of the linear structure 404 on the oxide 304.

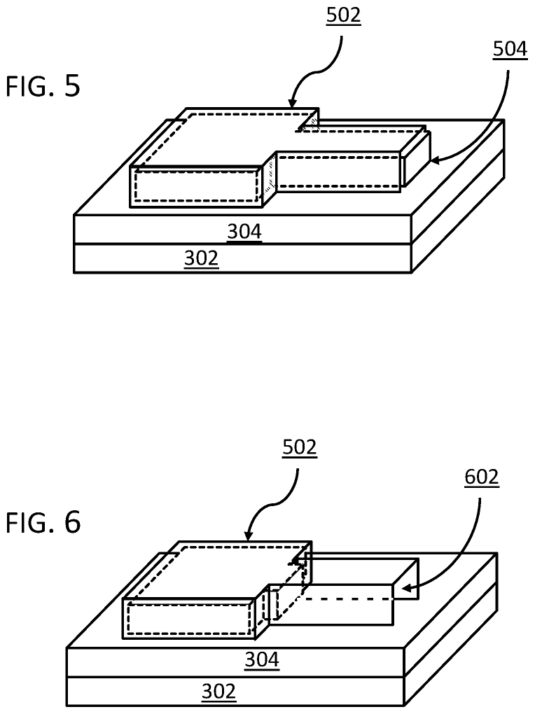

FIG. 5 shows that the blanket oxide 502 has been deposited over the source area and the linear structure. The source area in the linear structure is here not denoted with reference numerals but shown in dashed lines. Also visible is an opening 504 so that the linear structure opposite to the source area is exposed. To reach this fabrication status (i.e., blanket oxide 502 and opening 504), a series of different process steps may be required.

FIG. 6 shows the status of the blanket oxide 502 after the linear structure has been etched away under the blanket oxide, whereby a tunnel or hollow template 602 is created under the blanket oxide 502 in the area where the linear structure was before.

It should also be noted that reference numerals that have been mentioned in an earlier figure shall not be named again and again. Exemplary, in FIG. 6 this may be the silicon wafer 302 and the oxide 304. This practice will be continued throughout the remaining figures.

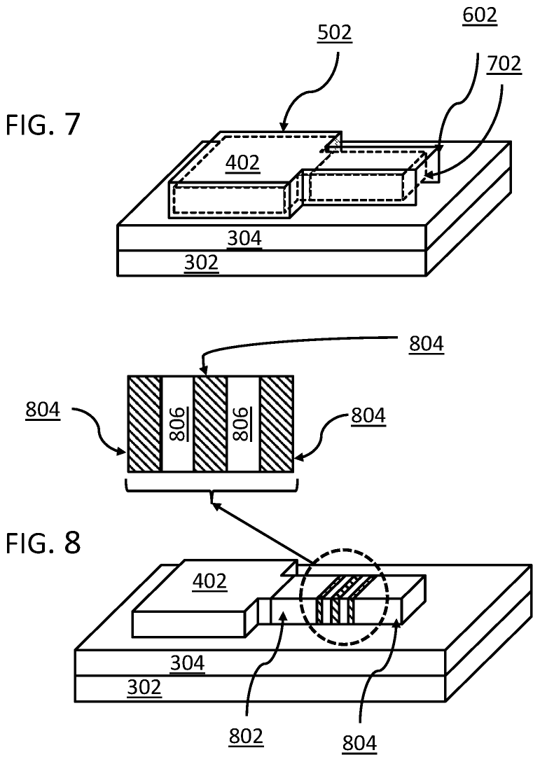

FIG. 7 shows the situation after epitaxial regrowth of a heterostructure 702 in the hollow template through the openings 602. The silicon source area has been used as a seed crystal for the linear heterostructure, i.e., a sequence of different semiconductor materials.

FIG. 8 shows the situation after the blanket oxide has been removed and the heterostructure 702 (compare FIG. 7) becomes completely visible. The linear structure, which was originally made of the same material as the source area 402 (e.g., Si), has now a first solid portion 802 of a first portion of a first semiconductor material, followed by a sequence of thin layers 804/806/804/806/804 of a second and a third semiconductor material. The final portion of the former Si-only linear structure is now built by a solid semiconductor segment 804 which again comprises the first semiconductor material. Not shown in the picture are one or more gate structures 406 in a plane equivalent to the plane of the third semiconductor material. However, if they would have been built in the step as illustrated by FIG. 3, these gate structures would also be available here. They have only been left out for comprehensibility reasons.

The dashed circle of the plurality of thin semiconductor layers are magnified in order to show the sequence of layers. Thereby, layers 804 are made from the second semiconductor material (e.g., InP) and the layers 806 are made from the third semiconductor material (e.g., InAs). For completeness reasons, it should also be mentioned that the segments 802 and 804 are made from the first semiconductor material, which may be InGaAs. This material mix may guarantee a good etch selectivity, so that the second semiconductor material may be removed easily.

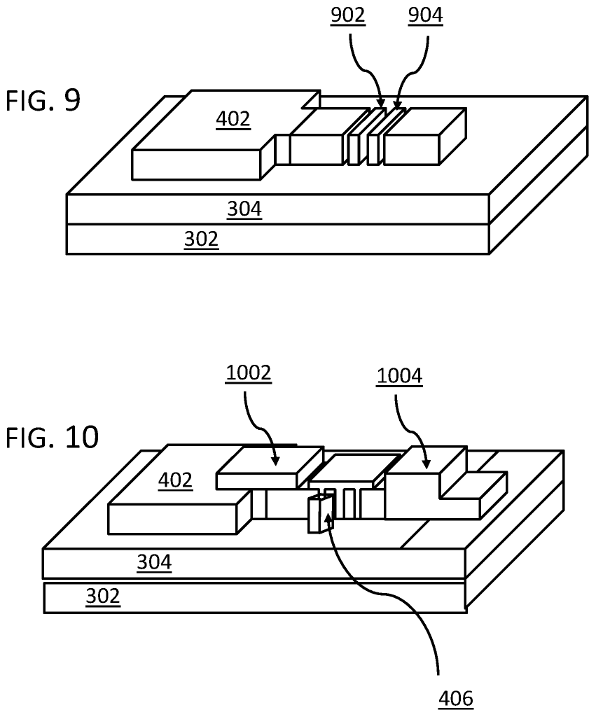

FIG. 9 shows the result of etching away the material of the second semiconductor material so that the layers 902 and 904 (corresponding to layers 806, compare FIG. 8) stand isolated. Again, also here, gate structures are not shown but may be potentially available. In any case, each of the layers 902 and 904 has a fin-like structure and may each represent quantum dot, and together coupled quantum dots.

FIG. 10 shows that the portions 802, 804 (compare FIG. 8) of the heterostructure are now covered with a metal contact, namely, metal source contact 1002 and metal drain contact 1004. Also shown in this figure is one of the gate structures 406 adjacent to one of the quantum dots, here, the fin-like structure 902 (reference numeral not shown, compare FIG. 9). Other positions of the gate structures will be discussed later.

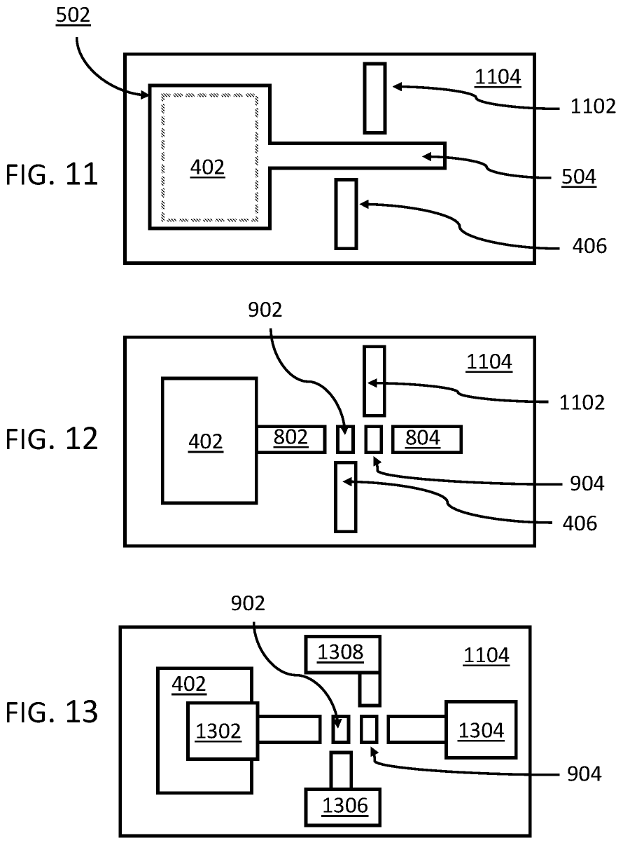

The following three figures, namely FIGS. 11, 12, 13 show the process steps in an abbreviated sequence: FIG. 11 shows the structuring of the source area 402, the gate structures 46 and 1102 as well as the linear structure 504, all covered by the blanket oxide 502 and all positioned directly on the oxide 1104 of the SOI substrate.

FIG. 12 shows a view on the structures after etching away the material in the hollow template, and refilling it with a heterostructure and separating the quantum dot structures 902 and 904. It is possible to add two more gates to the other sides of the quantum dot structures 902, 904, so that in total four gate structures are available for the two quantum dots 902, 904. These may be used for controlling the qubit device or for read-out purposes.

FIG. 13 shows the structures according to FIG. 12 in which additional metal contacts 1302 (source contact), 1304 (drain contact), 1306, 1308 (gate contacts) have also been added. It should be noted that to achieve such a result, a sequence of multiple masking and etching steps or doping processes may be required. It should also be noted that the gate semiconductor material is a doped Si material. For this, it may be helpful, that the top Si layer of the SOI structure is made from doped silicon.

The next couple of figures refer basically to the same heterostructure and quantum dot structures, where the gate structures are different to the alternative embodiment shown in the previous figures.

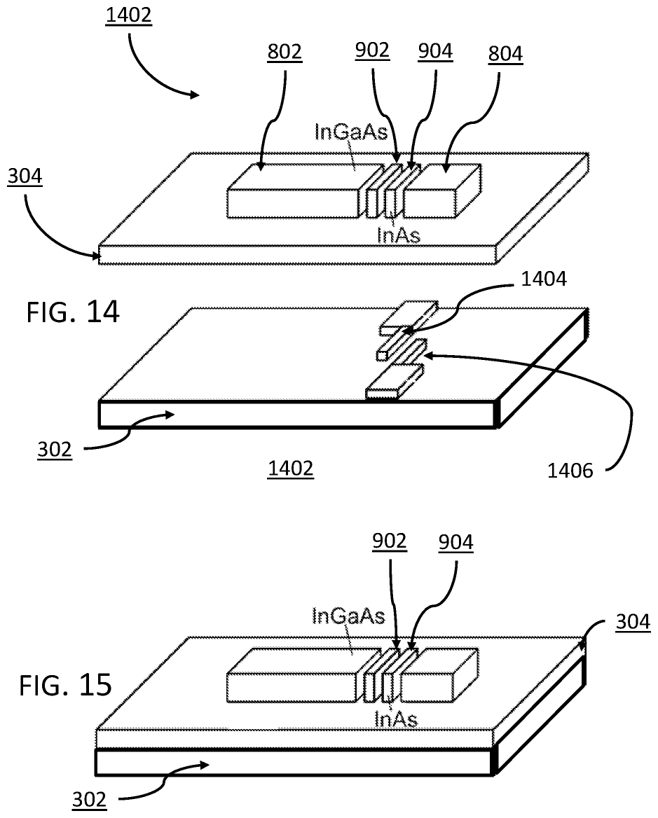

This may become more comprehensible starting with FIG. 14 showing a decomposed view 1402 of the layers 302—i.e., the silicon wafer layer, and layer 304 the oxide layer over which other structured components of the heterostructure are shown. Also shown are gate structures 1404, 1406 (as well as potential contact pads hit respective ends of the gate structures) which are positioned directly below the quantum dot structures 902, 904. Because the epitaxial regrowth of the heterostructure—in particular, including the quantum dots 902, 904—can be controlled in tight limits, it becomes feasible to position the layers 902, 904 exactly there, where the gate structures 1404, 1406 are buried in the oxide layer 304, i.e., in the gate areas.

It is assumed that layer 302 (silicon) and 304 (oxide) are—as they are in reality—on top one another, so that the gate structures 1404, 1406 would be buried in the oxide layer 304, hence, buried gates. This may easily be understood when viewing FIG. 15 which shows the Si layer 302 and the layer 304 directly atop each other.

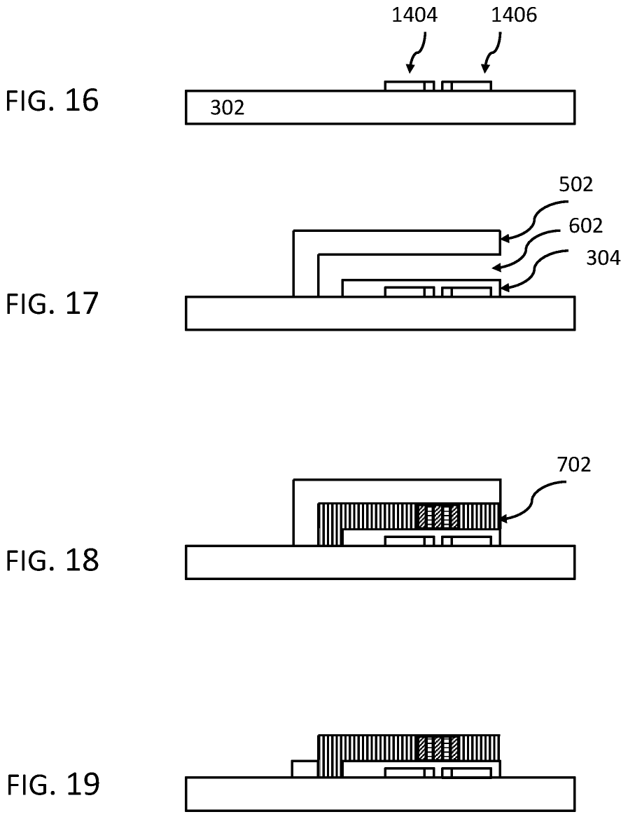

FIGS. 16 to 23 show a series fabrication step. FIG. 16 shows the buried doped gates 1404, 1406. They may either be positioned directly atop the SI wafer 302 or they may be isolated from the substrate 302.

FIG. 17 shows how the gate structures are covered by the oxide layer 304, the tunnel or hollow template 602, as well as the blanket oxide 502.

FIG. 18 shows the already re-grown heterostructure 702 inside the hollow template. FIG. 19 shows the structure now without the blanket oxide layer 502.

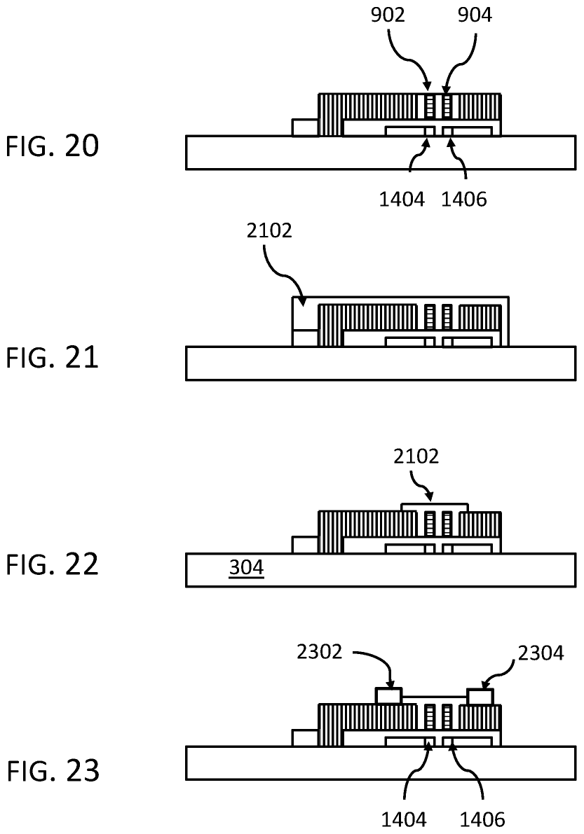

In FIG. 20, it is shown that the layers of the second semiconductor material had been removed. It becomes also clearly visible that the remaining fins or segments of the third semiconductor material (e.g., InAs), i.e., the quantum dots, stand right above the buried gate structures 1404, 1406.

FIG. 21 shows a covering process step with a dielectric 2102 which is filling also the spaces between the linear structure's first and third semiconductor material 802 (e.g., InGaAs) and 804 (e.g. InAs), and the space between the quantum dot structures 902, 904 which was filled with the second semiconductor material, e.g., InP.

In FIG. 22, the covering 2102 has now partially been removed—in particular, over the material of the first semiconductor, and in FIG. 23, a source contact 2302 and a drain contact 2304 have been deposited. The rest remains unchanged. With this, a completely functional qubit device comprising two coupled quantum dots 902, 904 has been realized, in this case using buried gates 1404, 1406.

The disclosed semiconductor structure device can be part of a semiconductor chip. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried inter-connections). In any case the chip is then integrated with other chips, discrete circuit elements, and/or other signal processing devices as part of either an intermediate product, such as a motherboard, or an end product. The end product can be any product that includes integrated circuit chips, ranging from toys and other low-end applications to advanced computer products having a display, a keyboard or other input device, a central processor or a quantum computer or parts of it.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A method comprising:
forming a semiconductor structure comprising isolated coupled quantum dots defining a physical spin qubit, wherein forming a semiconductor structure comprises:
providing silicon-on-isolator substrate comprising a doped silicon layer atop an isolator;
structuring said doped silicon layer to form a following structure, wherein the following structure comprises:
a source area structure,
a linear structure extending from said source area, wherein said linear structure has a first width which is smaller than a main area of said source area, and
gate structures extending vertically to a main extension direction of said linear structure, wherein said gate structures are isolated from said linear structure, and wherein said gate structures define at least a first and a second gate area,
covering said following structure with a blanket oxide layer;
removing said blanket oxide at a lateral end of said linear structure opposite to said source area such that an opening is created in said blanket oxide;
laterally etching back said linear structure between said blanket oxide and said isolator until an area near said source area is reached, thereby forming a hollow template between said isolator and said blanket oxide layer;
epitaxial and laterally filling said hollow template with a first semiconductor material different to said silicon such that said hollow template is filled up to a first length extending from said source area;
continuing said epitaxial and laterally filling said hollow template with an alternating sequence of lateral thin layers of a second semiconductor material and a third semiconductor material, such that at least two thin layers of said second semiconductor material and three thin layers of said third semiconductor material are deposited, such that said lateral thin layers of said third material are positioned in a planes, defined by said first and said second gate area; and
continuing said epitaxial and laterally filling said hollow template with said first semiconductor material until an end of said hollow template is reached.

2. The method according to claim 1, wherein
said first semiconductor material differs from said second semiconductor material;
said second semiconductor material differs from said third semiconductor material; and
wherein said first, said second, and said third semiconductor material are different from silicon.

3. The method according to claim 1, further comprising:
removing said blanket oxide layer; and
selectively removing said thin layers of said second semiconductor material such that an array of quantum dots of said third semiconductor material remains freestanding on said isolator and between said first semiconductor material.

4. The method according to claim 1, wherein said first semiconductor material is InGaAs.

5. The method according to claim 1, wherein said second semiconductor material is InP.

6. The method according to claim 1, wherein said third semiconductor material is InAs.

7. The method according to claim 1, further comprising:
filling gaps between said first semiconductor material and said third semiconductor material with a dielectric material.

8. The method according to claim 1, wherein said gate structures are fin-like structures that extend vertically away from said main extension direction of said linear structure on said oxide.

9. The method according to claim 1, wherein said gate structures are buried gates positioned in said oxide of said silicon-on-isolator substrate.

10. The method according to claim 8, further comprising:
depositing a metal source contact on an area of said first semiconductor material adjacent to said source area of said silicon layer; and
depositing a metal drain contact on an area of said first semiconductor material which related to said lateral end of said hollow template before said blanket oxide was removed.

11. The method according to claim 8, further comprising:
depositing a first metallic gate contact over said isolator of said substrate, wherein said first metallic gate contact is in electrical contact with a first gate structure of said gate structures; and
depositing a second metallic gate contact over said isolator of said substrate, wherein said second metallic gate contact is in electrical contact with a second gate structure of said gate structures.

12. A structured semiconductor device comprising:
isolated coupled quantum dots defining a physical spin qubit, wherein the structured semiconductor device comprises:
a silicon structure on an isolator building a source area;
a linear structure on an isolator, wherein said linear structure extends from said source area, wherein said linear structure has a width which is smaller than a main area of said source area, wherein said linear structure comprises:
a first area of a first semiconductor material, and a separated second area of said first semiconductor material,
an array of regularly spaced at least two thin, free-standing segments having a same lateral cross section as said first area and said second area of said first semiconductor material,
wherein said segments of said array are located on said isolator,
wherein said segments are isolated from each other by a dielectric material, and
gate structures extending vertically to a main extension direction of said linear structure, wherein said gate structures are isolated from said linear structure, and wherein said gate structures define at least a first and a second gate area, such that said array of said at least two thin, free-standing segments define at least two quantum dots as a basis for at least one physical spin qubit.

13. The device according to claim 12, wherein
said first semiconductor material is different to said second semiconductor material,
said second semiconductor material is different to said third semiconductor material, and
wherein said first, said second, and said third semiconductor material are different to silicon.

14. The device according to claim 12, wherein said first semiconductor material is InGaAs.

15. The device according to claim 12, wherein said second semiconductor material is InAs.

16. The device according to claim 12, further comprising:
gate structures separate and adjacent to alternating sides of said array of said quantum dots.

17. The device according to claim 12, wherein said gate structures are fin-like structures that extend vertically away from said main extension direction of said linear structure on the oxide.

18. The device according to claim 12, wherein said gate structures are buried gates positioned in said oxide of said silicon-on-isolator substrate.

19. The device according to claim 17, further comprising:
a metal source contact on said first area of said first semiconductor material; and
a metal drain contact on said second area of said first semiconductor material.

20. The device according to claim 17, further comprising:
a first metallic gate contact over said isolator substrate, wherein said first metallic gate contact is in electrical contact with a first gate structure of said gate structures; and
a second metallic gate contact over said isolator substrate, wherein said second metallic gate contact is in electrical contact with a second gate structure of said gate structures.
